(19) United States
(12) Patent Application Publication
(10) Pub. No.: US 2008/0280393 A1
(43) Pub. Date: Nov. 13, 2008

(54) METHODS FOR FORMING PACKAGE STRUCTURES

(75) Inventors: Hsin-Hui Lee, Kaohsiung (TW); Mirng-Ji Lii, Sinpu Township (TW)

Correspondence Address: DUANE MORRIS LLP (TSMC);IP DEPARTMENT, 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/746,442

(22) Filed: May 9, 2007

(51) Int. Cl. H01L 21/60; H01L 23/48

(52) U.S. Cl. 438/107; 257/698; 438/106; 438/115; 439/83; 257/E21.506

(57) ABSTRACT

A method for forming a semiconductor structure includes forming a first connector over at least one pad of a first substrate, the first connector having at least one curved sidewall. An encapsulation layer is formed at least partially over the first connector so as to partially expose a top surface of the first connector. A solder structure is formed, contacting the first connector.

### BACKGROUND OF THE INVENTION

1. Field of the Invention

The present invention relates, most generally, to methods for forming semiconductor structures, and more particularly to methods for forming package structures.

2. Description of the Related Art

With advances in electronic products, semiconductor technology has been applied widely in manufacturing memories, central processing units (CPUs), liquid crystal displays (LCDs), light emitting diodes (LEDs), laser diodes and other devices or chip sets. In order to achieve high-integration and high-speed requirements, dimensions of semiconductor integrated circuits have been reduced and various materials, such as copper and ultra low-k dielectrics, have been proposed and are being used along with techniques for overcoming manufacturing obstacles associated with these materials and requirements. Further, packages and packaging techniques that accommodate and incorporate small-dimension integrated circuits reduce chip package dimensions.

FIG. 1 is a flow chart showing a traditional process for forming a package. Step 101 is wafer incoming quality control (IQC) which identifies wafer material, checks nanotopography, particles, defects, scratches, wafer shapes, thickness, and/or semiconductor wafer supplier quality and monitors ongoing supplies. Step 103 forms a stress buffer layer and patterns the stress buffer layer over a wafer. Step 105 forms a re-routing metallic layer over the stress buffer layer. Step 107 patterns and etch the re-routing metallic layer. Step 109 forms another stress buffer layer over the patterned re-routing metallic layer. Step 111 forms solder ball pad openings. Step 113 forms an under bump metal (UBM) layer and pad openings exposing the UBM layer. Step 115 mounts solder balls over the BUM layer. Step 117 is a flux clean process. Step 119 laser marks the backside of the wafer. Step 121 sorts the wafer. Step 123 saws the wafer so as to create a plurality of individual dies. Step 125 packages each of the individual dies. Step 127 conducts a quality analysis to each of the packaged dies.

Another traditional process for forming a package involves the following. After forming various integrated circuits over a wafer, a patterned polyimide layer is formed over the integrated circuits. Then a UBM layer is formed over the polyimide layer. Copper patterns are plated over the UBM layer. A patterned dry film is form over the copper patterns, partially exposing the copper pattern. Copper posts are plated, contacting the copper patterns. A UBM removal process is used to remove portions of the UBM layer. An encapsulation layer is formed over the copper post and planarized. The substrate is then subjected to a backside grinding process. Solder balls are then mounted on the copper posts and subjected to a reflowing process. The backside of the substrate is subjected to a laser marking process. The substrate is then sawed and tested. The individual dies are then subjected to a taping process. However, the process are complex and the manufacturing costs of the package structures described above are high.

Based on the foregoing, package structures are desired.

### SUMMARY OF THE INVENTION

According to one aspect, provided is a method for forming a semiconductor structure includes forming a first connector over at least one pad of a first substrate, the first connector having at least one curved sidewall. An encapsulation layer is formed at least partially over the first connector so as to partially expose a top surface of the first connector. A solder structure is formed, contacting the first connector.

The above and other features will be better understood from the following detailed description of the exemplary embodiments of the invention that is provided in connection with the accompanying drawings.

### BRIEF DESCRIPTION OF THE DRAWINGS

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing. The drawings are mere exemplary embodiments and the scope of the present invention should not be limited thereto.

FIG. 1 is a flow chart showing a traditional process for forming a package.

FIGS. 2A-2L are schematic cross-sectional and corresponding top view drawings showing a sequence of processing steps in an exemplary method for forming a package structure.

FIGS. 2M and 2N are schematic cross-sectional views of exemplary semiconductor structures.

FIG. 2O is a schematic cross-sectional view of an exemplary semiconductor structure.

### DETAILED DESCRIPTION OF EXEMPLARY EMBODIMENTS

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus/device be constructed or operated in a particular orientation.

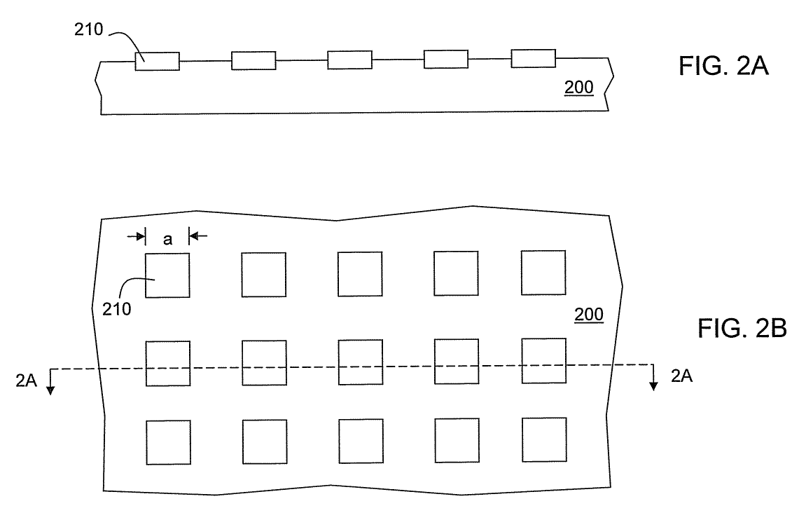

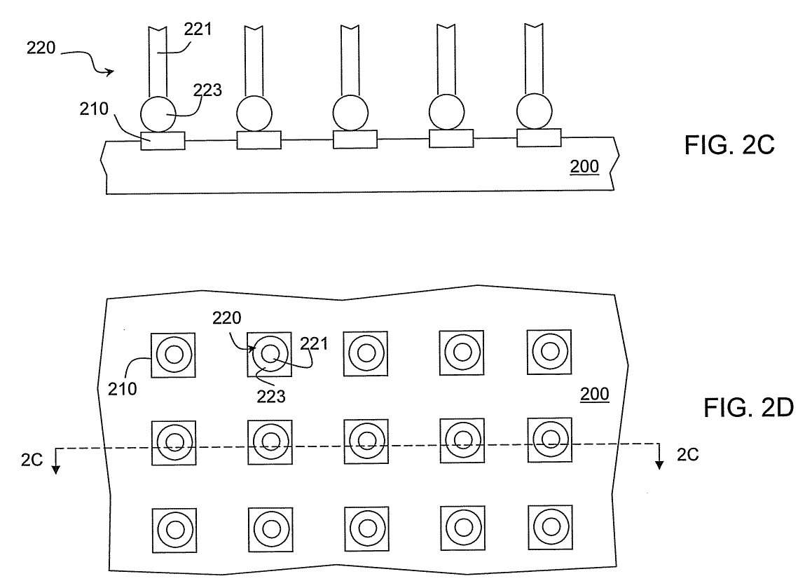

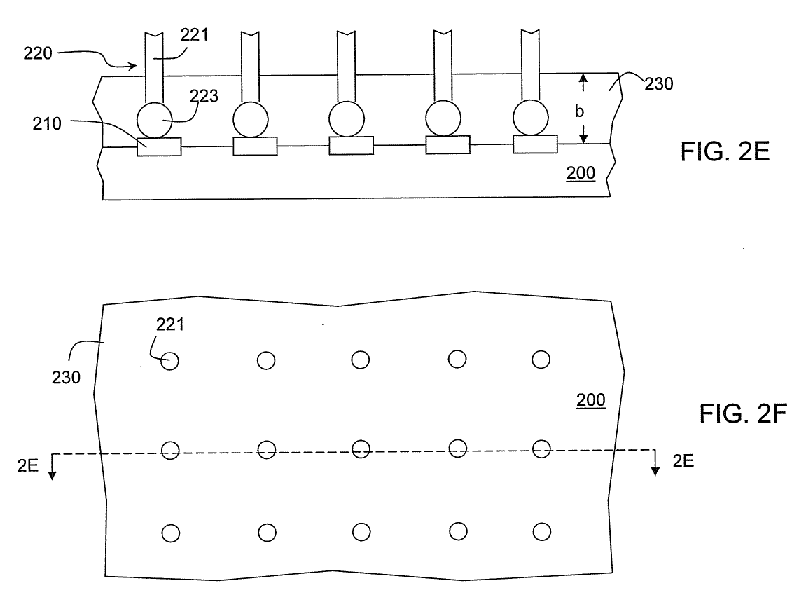

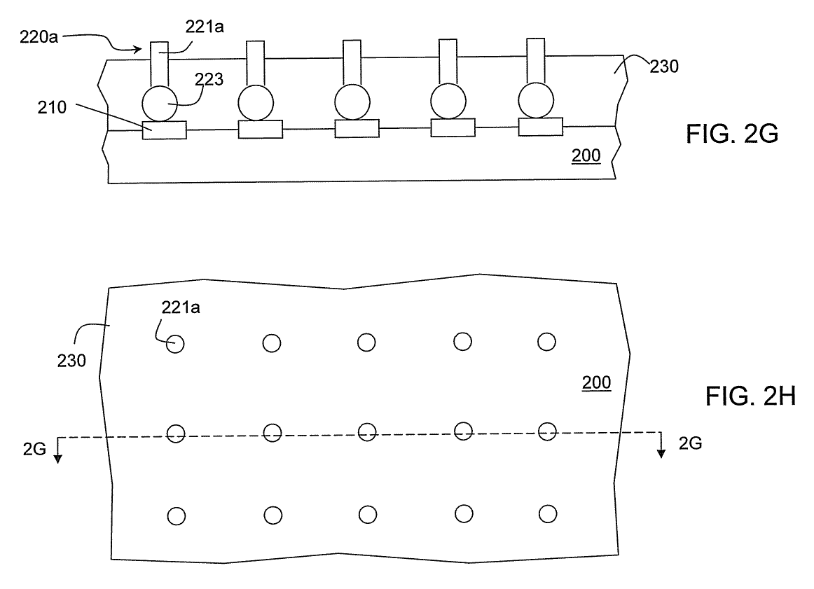

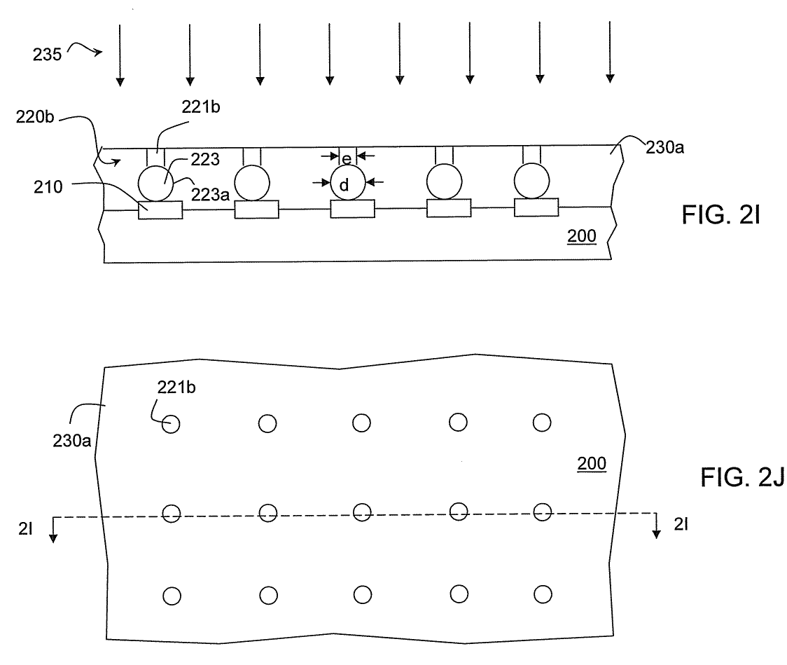

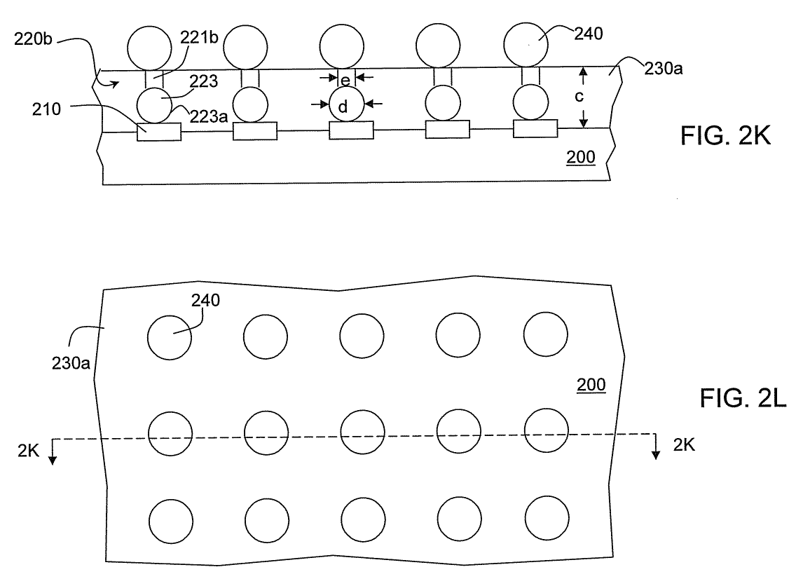

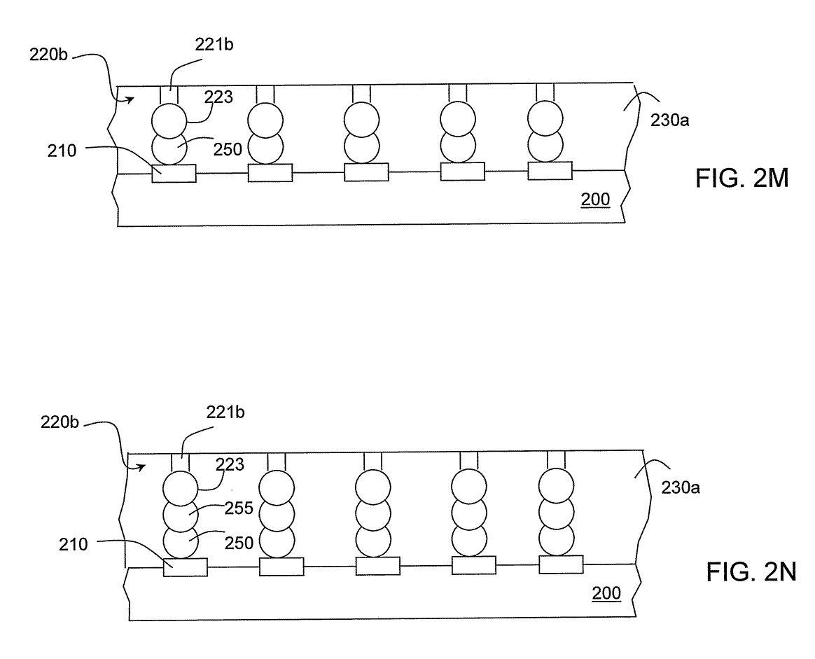

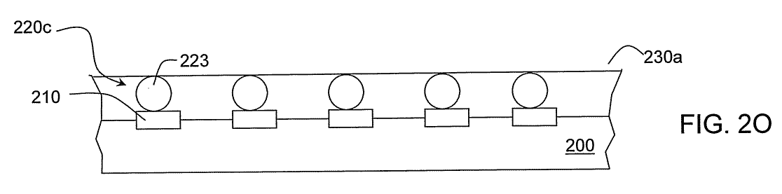

FIGS. 2A-2L are schematic drawings showing an exemplary method for forming a package structure.

FIG. 2A is a schematic cross-sectional view of an exemplary structure taken along a line 2A-2A of FIG. 2B. Referring to FIGS. 2A and 2B, at least one pad such as pads 210 are formed over a substrate 200. The substrate 200 can be a silicon substrate, a III-V compound substrate, a silicon/germanium (SiGe) substrate, a silicon-on-insulator (SOI) substrate, a display substrate such as a liquid crystal display (LCD), a plasma display, an electro luminescence (EL) lamp display, or a light emitting diode (LED) substrate in various exemplary embodiments. In some embodiments, at least one diode, transistor, device, circuit or other semiconductor structure or various combinations thereof (not shown) are formed below the pads 210 and electrically coupled thereto.

The pads 210 may comprise at least one material such as copper (Cu), aluminum (Al), aluminum copper (AlCu), aluminum silicon copper (AlSiCu), other conductive material or various combinations thereof. The pads 210 may be formed by, for example, chemical vapor deposition (CVD), physical vapor deposition (PVD), electroplating, electroless-plating, other deposition process that is adequate to for a thin film layer or various combinations thereof and a suitable patterning operation. In some embodiments, the pads 210 have a dimension “a” between about 40 μm and about 100 μm. Other dimensions may be used in other exemplary embodiments.

In some embodiments, the pads 210 may be formed at central regions of dies (not labeled) of the substrate 200 under which at least one diode, transistor, device, circuit, other semiconductor structure or various combinations thereof (not shown) are formed. In some embodiments, the at least one diode, transistor, device, circuit, other semiconductor structure or various combinations thereof (not shown) formed below the pads 210 may be referred to as a circuit under pad (CUP) structure. In other embodiments, the pads 210 may be formed in the perimeter of the dies (not shown) of the substrate 200.

FIG. 2C is a schematic cross-sectional view of an exemplary structure taken along a line 2C-2C of FIG. 2D. Referring to FIGS. 2C and 2D, at least one connector such as connectors 220 are wire bonded over the respective pads 210. The connectors 220 are formed, providing electrical connection between the pads 210 and solder structures 240 (as will be shown in FIG. 2K). Each of the connectors 220 may include a top region 221 such as a wire region and a bottom region 223 such as a ball region. The connectors 220 may comprise at least one material such as Cu, gold (Au), aluminum (Al) or other metallic material or various combinations thereof. In some embodiments, the wire bonding process used to bond connectors 220 to corresponding pads 210 may use a bonding force between about 10 grams (g) and about 30 g and/or a power between about 50 milli-Amps (mA) and about 150 mA. Other bonding force and/or power may be used in other exemplary embodiments. The scope of the invention, however, is not limited thereto.

FIG. 2E is a schematic cross-sectional view of an exemplary structure taken along a line 2E-2E of FIG. 2F. Referring to FIGS. 2E and 2F, an encapsulation material 230 is formed over the pads 210 and the ball regions 223. The wire region 221 may extend above the top surface (not labeled) of the encapsulation material 230. The encapsulation material 230 may be formed of at least one of epoxy, polyimide, or another encapsulant that is adequate to protect the ball regions 223 or various combinations thereof. The encapsulation material 230 may be formed by a spin-coating step or an under-filling step in various exemplary embodiments. In some embodiments, the encapsulation material 230 may have a thickness “b” between about 50 μm and about 100 μm. However, thickness “b” may be other dimensions in other exemplary embodiments.

FIG. 2G a schematic cross-sectional view of an exemplary structure taken along a line 2G-2G of FIG. 2H. Referring to FIGS. 2G and 2H, the wire regions 221 shown in FIG. 2E are cut and portions of the wire regions 221 are removed so as to form wire regions 221a of modified connectors 220a. In some embodiments, the portions of the wire regions 221 may be removed, such that a subsequent removal process described in conjunction with FIG. 2I can be desirably conducted.

In some embodiments, the cutting step described in conjunction with FIG. 2G may be conducted before the formation of the encapsulation material 230 shown in FIG. 2E.

FIG. 2I is a schematic cross-sectional view of an exemplary structure taken along a line 2I-2I of FIG. 2J. Referring to FIGS. 2I and 2J, a removal process 235 is used to remove portions of the wire regions 221a (shown in FIG. 2G) and a portion of the encapsulation material 230 (shown in FIG. 2G) so as to form the wire regions 221b and the encapsulation layer 230a, respectively. Each of the connectors 220b includes the wire region 221b and the ball region 223. The removal process 235 may comprise, for example, a chemical-mechanical polishing (CMP) step, an etch process step, other removal process or combinations thereof.

FIG. 2K is a schematic cross-sectional view of an exemplary structure taken along a line 2K-2K of FIG. 2L. After the removal process 235, top surfaces (not labeled) of the wire regions 221b may be exposed for electrical connection with solder structures 240 (as shown in FIG. 2K). In some embodiments, the wire regions 221b of the connectors 220b and the encapsulation layer 230a may have a substantially level surface. In other embodiments, the wire regions 221b of the connectors 220b and the encapsulation layer 230a may not be substantially level as long as the exposed surfaces (not labeled) of the wire regions 221b may desirably contact solder structures 240 (shown in FIG. 2K) for electrical connection.

The encapsulation layer 230a may include a thickness “c” between about 50 μm and about 100 μm in some embodiments. However, other dimension of the thickness “c” may be used in other exemplary embodiments.

Referring again to FIGS. 2K and 2L, at least one solder structure such as solder structures 240 are formed over the encapsulation layer 230a, contacting the respective wire regions 221b. The solder structures 240 may comprise, for example, solder balls and/or solder bumps. In some embodiments, the solder structures 240 may comprise at least one material such as eutectic tin-lead (Sn—Pb) solder, high lead solder, lead free solder, another solder material or various combinations thereof.

Referring again to FIG. 2K, the connectors 220b including the ball regions 223 and the wire regions 221b extend from the pads 210 to the top surface (not shown) of the encapsulation layer 230a. Each of the ball regions 223 may have at least one curved sidewall such as sidewall 223a. In some embodiments, the diameter “d” of the ball regions 223 may be larger than the width “e” of the wire regions 221b.

After forming the solder structures 240, the structure shown in FIG. 2K may be formed into a desired package structure by being subjected to a reflowing step, a flux cleaning step, a backside grinding step, a laser marking step, a substrate sorting step, a substrate sawing step, a package step and/or a quality analysis step. From the foregoing, one of ordinary skill in the art is able to form desired package structures.

As described in conjunction with FIGS. 2C and 2K, the connectors 220 may be wire bonded over the pads 210 and the solder structures 240 are bonded over modified connectors 220b. The wire bonding force and the solder bonding force may compress the ball regions 223 of the connectors 220b, such that the ball regions 223 of the connectors 220b may have flat bottom surfaces (not shown) that contact the pads 210. In some embodiments, the ball regions 223 in the cross-sectional view may substantially be a circle, an oval, a flask-shaped structure, a round-bottom flask-shaped structure or a volumetric flask-shaped structure.

FIG. 2M is a schematic cross-sectional view of another exemplary semiconductor structure. At least one connector such as connectors 250 may be formed between the pads 210 and the connectors 220b. In some exemplary embodiments, the connectors 250 may be wire bonded over the pads 210. The material of the connectors 250 and the methods for forming the connectors 250 may be similar to that of the connectors 220b described in conjunction with FIG. 2C. By forming the connectors 250 between the pads 210 and the connectors 220b, the semiconductor structure shown in FIG. 2M may have a desired package thickness or height.

FIG. 2N is a schematic cross-sectional view of an exemplary semiconductor structure. At least one connector such as connectors 255 may be formed between the connectors 250 and 220b. In some exemplary embodiments, the connectors 255 may be wire bonded over the connectors 250. The material of the connectors 255 and the methods for forming the connectors 255 may be similar to that of the connectors 220b described in conjunction with FIG. 2C. By forming the connectors 255 between the connectors 220b and 250, the semiconductor structure shown in FIG. 2N may have a desired package thickness or height.

FIG. 2O is a cross-sectional view of another exemplary package structure. In some embodiments, the removal process 235 may substantially remove the wire regions 221 so as to partially expose the ball regions 223 of the connectors 220c as shown in FIG. 20. The exposed top surface (not labeled) of the ball regions 223 may contact with solder structures 240 shown in FIG. 2K.

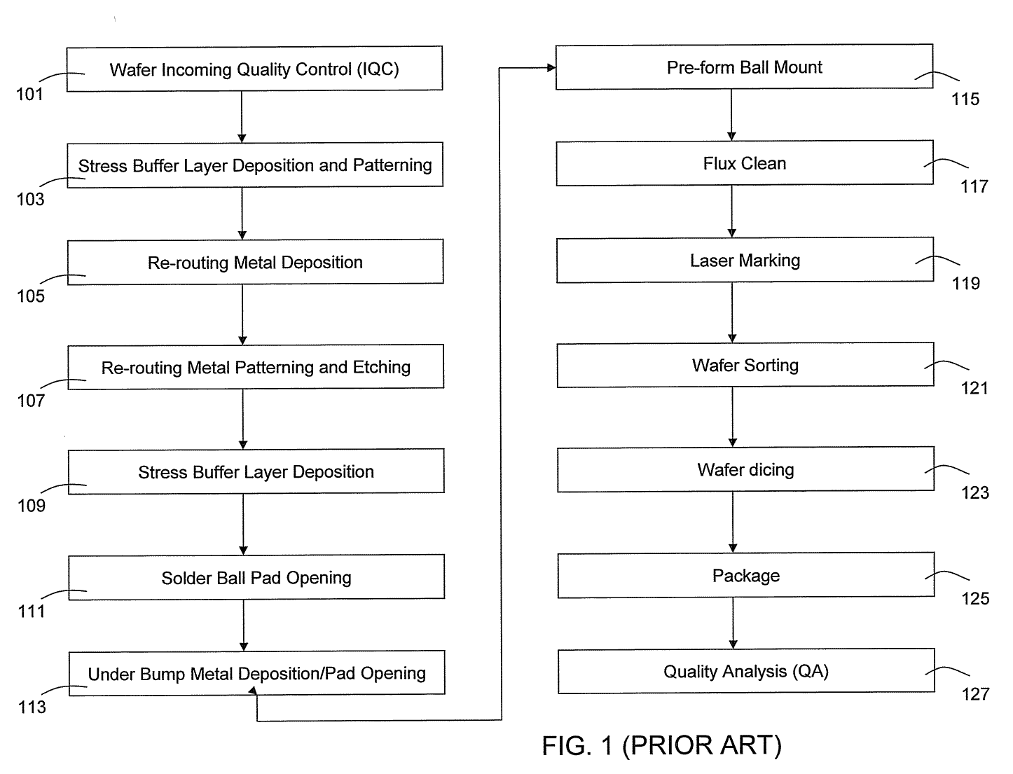

Referring again to FIG. 1, the process steps 103-113 are carried out to form conductive posts coupled to the pads, such that step 115 may be used to mount solder balls on the conductive posts for electrical connection. As described in conjunction with FIG. 1, the process steps 103-113 form various layers such as the stress buffer layers, the re-routing metal layer and the UBM layer. Further, the various process steps for patterning and removing portions of these material layers take a long process time. The process steps 103-113 thus are complicated and increase manufacturing costs. Unlike process steps 103-113, the process shown in FIGS. 2A-2I may replace the steps 103-113 so as to form the connectors 220b for electrical connection between the pads 210 and the solder structures 240. Since the process uses the wire bonding process to form the connector 220 (shown in FIG. 2C), the process for forming the connectors 220b is simplified and the costs of manufacturing the connectors 220b may be desirably reduced if compared with the process steps 103-113 shown in FIG. 1.

Although the present invention has been described in terms of exemplary embodiments, it is not limited thereto. Rather, the appended claims should be construed broadly to include other variants and embodiments of the invention which may be made by those skilled in the field of this art without departing from the scope and range of equivalents of the invention.

What is claimed is:

1. A method for forming a semiconductor structure, the method comprising:
forming a first connector over at least one pad of a first substrate, the first connector having at least one curved sidewall;
forming an encapsulation layer at least partially over the first connector so as to partially expose a top surface of the first connector; and
forming a solder structure contacting the first connector.

2. The method of claim 1, wherein the step of forming a first connector comprises:
wire bonding a ball on the at least one pad, the ball having a wire extending therefrom; and
cutting the wire.

3. The method of claim 2, wherein the step of forming an encapsulation layer comprises:
coating an encapsulation material at least partially covering the ball, such that the wire extends above a top surface of the encapsulation material; and
removing a portion of the encapsulation material so as to form the encapsulation layer, and a portion of the cut wire so as to form the first connector.

4. The method of claim 3, wherein the removing step comprises chemical-mechanical polishing (CMP).

5. The method of claim 1 further comprising forming a second connector between the at least one pad and the first connector.

6. The method of claim 1 further comprising bonding the solder structure to a second substrate.

7. The method of claim 1 further comprising sawing the first substrate to generate a plurality of individual dies.

8. A method for forming a semiconductor structure, the method comprising:
forming an array of first connectors over a plurality of pads in a central region of a first substrate, at least one of the first connectors having at least one curved sidewall;
forming an encapsulation layer at least partially over the first connectors so as to partially expose top surfaces of the first connectors; and
forming a plurality of solder structures contacting the respective first connectors.

9. The method of claim 8, wherein the step of forming an array of first connectors comprises:
wire bonding an array of balls on the pads, each ball having a wire extending therefrom; and
cutting at least one of the wires.

10. The method of claim 9, wherein the step of forming an encapsulation layer comprises:
coating an encapsulation material at least partially covering the balls, such that the wires extend above a top surface of the encapsulation material; and
removing a portion of the encapsulation material so as to form the encapsulation layer, and portions of the cut wire regions so as to form the first connectors.

11. The method of claim 10, wherein the removing step comprises chemical-mechanical polishing (CMP).

12. The semiconductor method of claim 8 further comprising forming at least one second connector between the pads and the first connectors.

13. The semiconductor method of claim 8 further comprising bonding the solder structures to a second substrate.

14. The semiconductor method of claim 8 further comprising sawing the first substrate to generate a plurality of individual dies.
